(19) United States
(12) Patent Application Publication
(10) Pub. No.: US 2012/0326152 A1
(43) Pub. Date: Dec. 27, 2012

(54) THIN FILM TRANSISTOR SUBSTRATE, DISPLAY PANEL HAVING THE SAME AND METHOD OF MANUFACTURING

(76) Inventors: Tae-Young CHOI, Seoul (KR); Doohyoung LEE, Suwon-si (KR); Yeontaek JEONG, Seoul (KR); Seon-Pil JANG, Seoul (KR); Bo Sung KIM, Seoul (KR); Youngmin KIM, Yongin-si (KR)

(21) Appl. No.: 13/526,195

(22) Filed: Jun. 18, 2012

(30) Foreign Application Priority Data
Jun. 22, 2011 (KR) 10-2011-0060705

(51) Int. Cl. H01L 29/786; H01L 21/336

(52) U.S. Cl. 257/59; 438/158; 257/57; 257/E29.273; 257/E21.411

(57) ABSTRACT

A thin film transistor substrate includes a base substrate; a first insulating layer disposed on the base electrode; source and drain electrodes disposed on the first insulating layer to be spaced apart from each other; a semiconductor layer disposed on the source electrode, the drain electrode, and the first insulating layer; a second insulating layer disposed on the semiconductor layer; and a gate electrode disposed on the second insulating layer to overlap with the source electrode and the drain electrode.

### CROSS-REFERENCE TO RELATED APPLICATION

This application relies for priority upon Korean Patent Application No. 10-2011-0060705 filed on Jun. 22, 2011, the contents of which are herein incorporated by reference in its entirety.

### BACKGROUND

1. Field of Disclosure

The present invention relates to a thin film transistor substrate capable of preventing deterioration characteristics thereof, a display panel having the thin film transistor substrate, and a method of manufacturing the thin film transistor substrate.

2. Description of the Related Art

In general, a display panel includes a thin film transistor substrate on which a plurality of pixels are arranged and a color filter substrate facing the thin film transistor substrate. The thin film transistor substrate includes a plurality of thin film transistors to drive the pixels. Each thin film transistor includes amorphous silicon as a semiconductor layer. An alternative to amorphous silicon is a recently researched and developed organic or oxide material that is able to be formed by a printing process or an inkjet process.

However, when the oxide semiconductor material is used to form the thin film transistor an etch stopper is used to pattern the oxide semiconductor material while the oxide semiconductor material is wet-etched causing deterioration in the characteristics of the oxide semiconductor material.

### SUMMARY

Exemplary embodiments of the present invention provide a thin film transistor substrate capable of preventing deterioration characteristics thereof.

Exemplary embodiments of the present invention provide a display panel having the thin film transistor substrate.

Exemplary embodiments of the present invention provide a method of manufacturing the thin film transistor substrate.

According to the exemplary embodiments, a thin film transistor substrate includes a base electrode disposed on a substrate; a first insulating layer disposed on the base substrate; a source electrode disposed on the first insulating layer; a drain electrode disposed on the first insulating layer to be spaced apart from the source electrode; a semiconductor layer disposed on the source electrode, the drain electrode, and the first insulating layer; a second insulating layer disposed on the semiconductor layer; and a gate electrode disposed on the second insulating layer to overlap with the source electrode and the drain electrode.

According to the exemplary embodiments, a display panel includes a substrate and a plurality of pixels disposed on the substrate.

Each pixel includes a base electrode disposed on the substrate; a first insulating layer disposed on the base electrode; a source electrode disposed on the first insulating layer; a drain electrode disposed on the first insulating layer and spaced apart from the source electrode; a semiconductor layer disposed on the source electrode, the drain electrode, and the first insulating layer; a second insulating layer disposed on the semiconductor layer; and a gate electrode disposed on the second insulating layer and overlapped with the source electrode and the drain electrode.

According to the exemplary embodiments, a method of manufacturing a thin film transistor substrate is provided as follows. A base electrode is formed on a substrate and a first insulating layer is formed on the base electrode. Then, a source electrode and a drain electrode are formed on the first insulating layer to be spaced apart from each other. A semiconductor layer is then formed on the source electrode, the drain electrode, and the first insulating layer. A second insulating layer is formed on the semiconductor layer, and a gate electrode is formed on the second insulating layer to overlap with the source electrode and the drain electrode. A third insulating layer is formed on the second insulating layer to cover the gate electrode.

According to the above, since an etch process of patterning the semiconductor layer does not need to be performed after forming the semiconductor layer, detoriation characteristic of the semiconductor layer may be prevented. In addition, since a photolithography process applied to pattern the semiconductor layer may be omitted, a manufacturing cost of the display panel may be reduced and a manufacturing process may be simplified.

### BRIEF DESCRIPTION OF THE DRAWINGS

The above and other features of the present invention will become readily apparent by reference to the following detailed description when considered with the accompanying drawings wherein:

FIG. 1 is an exploded perspective view showing a display panel according to an exemplary embodiment of the present invention;

FIG. 2 is a plan view showing a portion of a first substrate of FIG. 1;

FIG. 3 is cross-sectional views respectively taken along lines I-I′, II-II′, III-III′, and IV-IV′ of FIG. 2;

FIG. 4 is a graph showing voltage-current characteristics of an oxide semiconductor transistor;

FIG. 5A is a plan view showing a result of performing a first photolithography process of a manufacturing method of a thin film transistor substrate according to an exemplary embodiment of the present invention;

FIG. 5B is cross-sectional views respectively taken along lines I-I′, II-II′, III-III′, and IV-IV′ of FIG. 5A;

FIG. 6A is a plan view showing a result of performing a second photolithography process of a manufacturing method of a thin film transistor substrate according to an exemplary embodiment of the present invention;

FIG. 6B is cross-sectional views respectively taken along lines I-I′, II-II′, III-III′, and IV-IV′ of FIG. 6A;

FIG. 7A is a plan view showing a result of performing a third photolithography process of a manufacturing method of a thin film transistor substrate according to an exemplary embodiment of the present invention;

FIG. 7B is cross-sectional views respectively taken along lines I-I′, II-II′, III-III′, and IV-IV′ of FIG. 7A;

FIG. 8A is a plan view showing a result of performing a fourth photolithography process of a manufacturing method of a thin film transistor substrate according to an exemplary embodiment of the present invention; and

FIG. 8B is cross-sectional views respectively taken along lines I-I′, II-II′, III-III′, and IV-IV′ of FIG. 8A.

### DETAILED DESCRIPTION

Hereinafter, the present invention will be explained in detail with reference to the accompanying drawings.

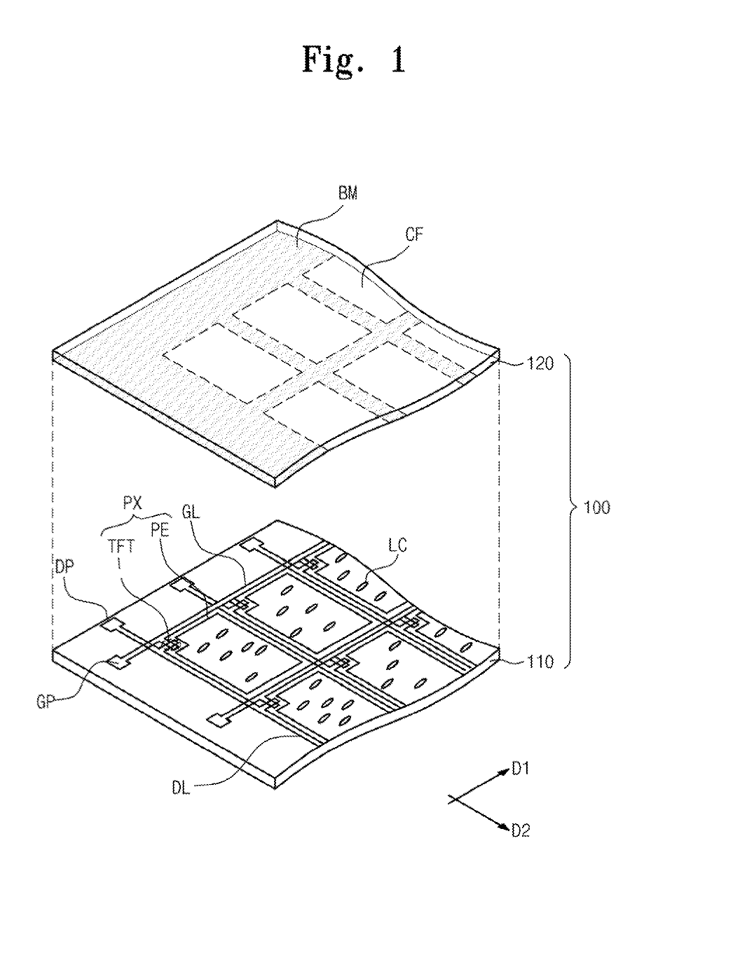

FIG. 1 is an exploded perspective view showing a display panel according to an exemplary embodiment of the present invention.

The display panel 100 includes a plurality of pixels PX to display an image. The display panel 100 may be a liquid crystal display panel, an organic light emitting display panel, an electrophoretic display panel, an electro-wetting display panel, or a microelectromechanical system display panel. In an exemplary embodiment the liquid crystal display panel has been described as the display panel 100.

Referring to FIG. 1, the display panel 100 includes a first substrate 110, a second substrate 120 facing the first substrate 110, and a liquid crystal layer LC disposed between the first substrate 110 and the second substrate 120.

The first substrate 110 includes a plurality of gate lines GL extended in a first direction D1 and a plurality of data lines DL extended in a second direction D2 crossing the first direction D1 and insulated from the gate lines DL.

Pixels PX are arranged between the gate lines GL and the data lines DL. In detail, as shown in FIG. 1, each pixel PX is disposed between two adjacent gate lines GL and between two adjacent data lines DL, but it should not be limited thereto or thereby.

Each pixel PX includes a thin film transistor TFT connected to a corresponding gate line of the gate lines GL and a corresponding data line of the data lines DL and a pixel electrode PE connected to the thin film transistor TFT.

Gate pads GP respectively connected to the gate lines GL and data pads DP respectively connected to the data lines DL are disposed in a peripheral area of the first substrate 110. In detail, each gate pad GP is extended from at least one end of a corresponding gate line of the gate lines GL, and each data pad DP is extended from at least one end of a corresponding data line of the data lines DL. The gate pads GP are connected to external wires to apply gate signals to the thin film transistors TFT and the data pads DP are connected to external wires to apply data signals to the thin film transistors TFT.

The second substrate 120 includes a plurality of color filters CF respectively corresponding to the pixels PX and a black matrix BM disposed between the color filters CF to block the light passing between the pixels PX. The color filters CF include color pixels or materials that display red, green, and blue colors. In addition, the second substrate 120 may further include a common electrode (not shown) disposed on the color filters CF and the black matrix BM. The common electrode faces the pixel electrode PE to form an electric field on the liquid crystal layer LC.

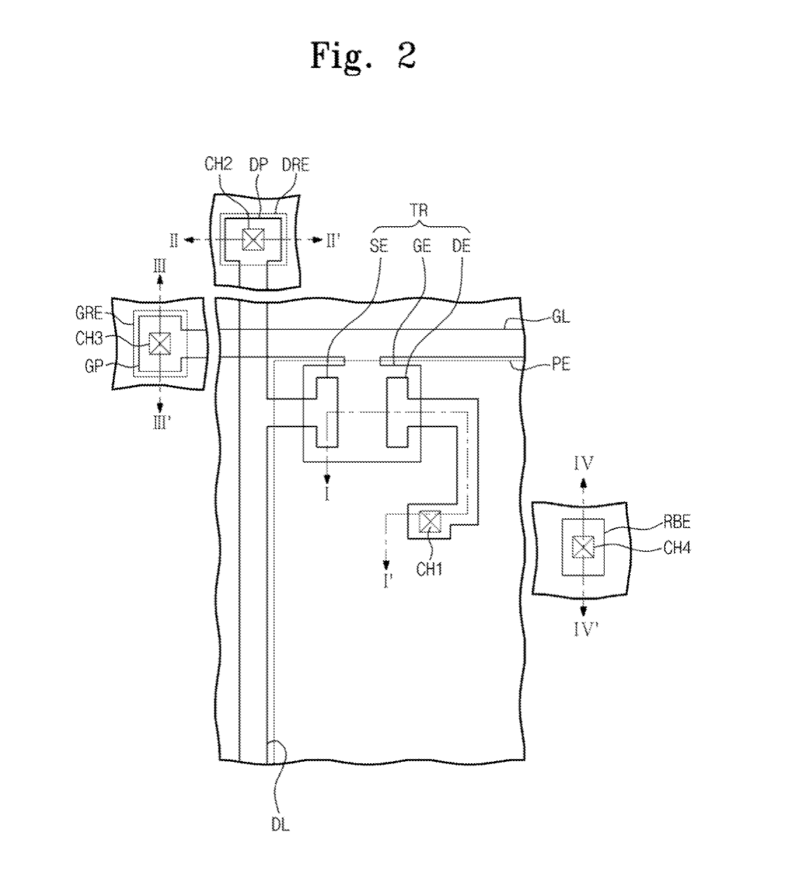

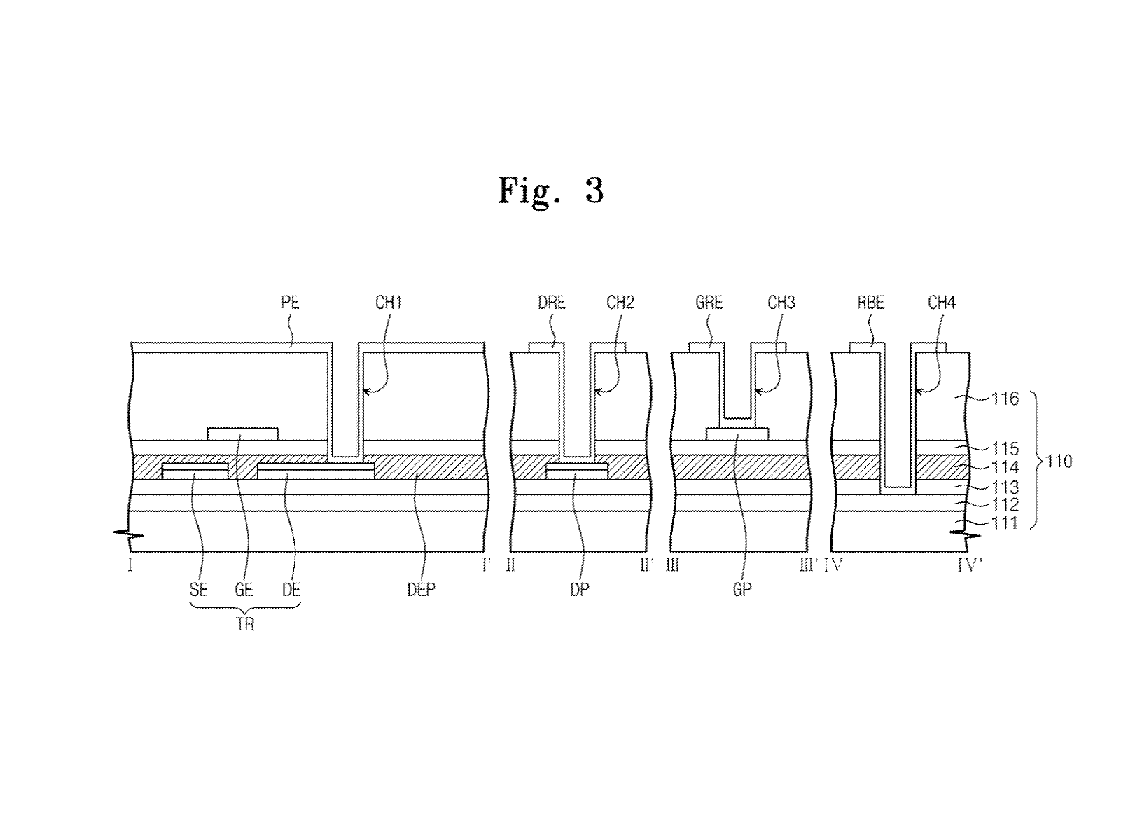

FIG. 2 is a plan view showing a portion of a first substrate of FIG. 1 and FIG. 3 is cross-sectional views respectively taken along lines I-I′, II-II′, III-III′, and IV-IV′ of FIG. 2.

In the present exemplary embodiment, the pixels have the same structure and function, and thus one pixel has been shown in FIG. 2 together with the gate and data lines adjacent to the one pixel. In addition, the gate and data pads corresponding to the one pixel have been shown in FIG. 2.

Referring to FIG. 2, the first substrate 110 includes the gate line GL extended in a first direction D1 and a data line DL extended in a second direction D2. The gate pad GP is connected to at least one end of the gate line GL and the data pad DP is connected to at least one end of the data line DL.

The thin film transistor TFT including a gate electrode GE branched from the gate line GL, a source electrode SE branched from the data line DL, and a drain electrode DE spaced apart from the source electrode SE. The thin film transistor TFT is turned on by a gate-on signal applied through the gate line GL allowing a data signal applied through the data line DL to pass to the drain electrode DE. The drain electrode DE is connected to the pixel electrode PE through a contact hole CH1.

Referring to FIGS. 2 and 3, the first substrate 110 includes a base substrate 111. A base electrode 112 is disposed on the base substrate 111. The base electrode 112 may be formed in a single or plural number to partially or entirely cover an upper surface of the base substrate 111. The base electrode 112 may be a transparent or non-transparent electrode. In detail, the base electrode 112 may be the transparent electrode including indium tin oxide (ITO), indium zinc oxide (IZO), indium tin zinc oxide (ITZO), or gallium zinc oxide (GZO), or the non-transparent electrode including an opaque metal material.

A first insulating layer 113 is disposed on the base electrode 112. The first insulating layer 113 may include an oxide material, a nitride material, or a transparent insulative material, e.g., silicon nitride (SiNx), silicon oxide (SiOx).

The data line DL, the source electrode SE, the drain electrode DE, and the data pad DP are disposed on the first insulating layer 113. Each of the data line DL, the source electrode SE, the drain electrode DE, and the data pad DP may have a double-layer structure of a first metal layer and a second metal layer disposed on the first metal layer. In the present exemplary embodiment, the first metal layer may include chromium (Cr) or chromium oxide (Cr₂O₃) and the second metal layer may include aluminum neodymium (AlNd).

A semiconductor layer 114 is disposed on the first insulating layer 113, the source electrode SE, the drain electrode DE, and the data pad DP. The semiconductor layer 114 may include an oxide compound. In detail, the semiconductor layer 114 may include at least one of InGaZnO, ZnO, ZrInZnO, InZnO, InGaZnO₄, ZnInO, In2O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, or TiSrO₃.

A second insulating layer 115 is disposed on the semiconductor layer 114. The second insulating layer 115 may include an oxide material, a nitride material, or a transparent insulative material, for example, silicon nitride (SiNx) or silicon oxide (SiOx).

The gate line GL, the gate electrode GE, and the gate pad GP are disposed on the second insulating layer 115. In addition, a third insulating layer 116 is disposed on the gate electrode GE and the gate pad GP. The third insulating layer 116 may include an organic material, such as resist polyimide resin, acryl resin, etc. As shown in FIG. 3, each of the gate electrode GE and the gate pad GP has a single-layer structure, but it should not be limited thereto or thereby.

The pixel electrode PE, a data receiving electrode DRE, a gate receiving electrode GRE, and a reverse-bias input electrode RBE are disposed on the third insulating layer 116. The pixel electrode PE, the data receiving electrode DRE, the gate receiving electrode GRE, and the reverse-bias input electrode RBE may be formed of indium tin oxide or indium zinc oxide.

The pixel electrode PE is connected to the drain electrode DE through a first contact hole CH1 that is formed through the second insulating layer 115, the semiconductor layer 114, and the third insulating layer 113 to expose at least portion of the drain electrode DE. The data receiving electrode DRE is connected to the data pad DP through a second contact hole CH2 that is formed through the second insulating layer 115, the semiconductor layer 114, and the third insulating layer 116 to expose the data pad DP. The gate receiving electrode GRE is connected to the gate pad GP that is formed through the third insulating layer 116 to expose the gate pad GP. In addition, the reverse-bias input electrode RBE is connected to the base electrode 112 through a fourth contact hole CH4 that is formed through the first insulating layer 113, the second insulating layer 115, the semiconductor layer 114, and the third insulating layer 116.

The data receiving electrode DRE, the gate receiving electrode GRE, and the reverse-bias input electrode RBE are connected to external wires to respectively receive a data signal, a gate signal, and a reverse-bias voltage.

The reverse-bias voltage has a voltage level of about −20 volts to about 0 volts with respect to a reference voltage to make at least a portion or an entire portion of the semiconductor layer 114 a depletion layer DEP.

In detail, the depletion layer DEP may be formed over the whole surface of the semiconductor layer 114 according to a level of the reverse-bias voltage. When changed to the depeletion layer, the semiconductor layer 114 may serve as an insulating layer and a current does not flow between the source electrode SE and the drain electrode DE. However, when the gate-on voltage is applied to the gate electrode GE, the semiconductor layer 114 between the gate electrode GE, the source electrode SE, and the drain electrode DE is changed to a non-depletion layer that operates as a conductive channel. Thus, the conductive channel may be formed between the source electrode SE and the drain electrode DE, and the thin film transistor TFT may be operated as a switching device.

A thickness in cross-section and a width in plan view of the semiconductor layer changed to the depletion layer may be varied depending on the level of the gate-on voltage and the level of the reverse-bias voltage.

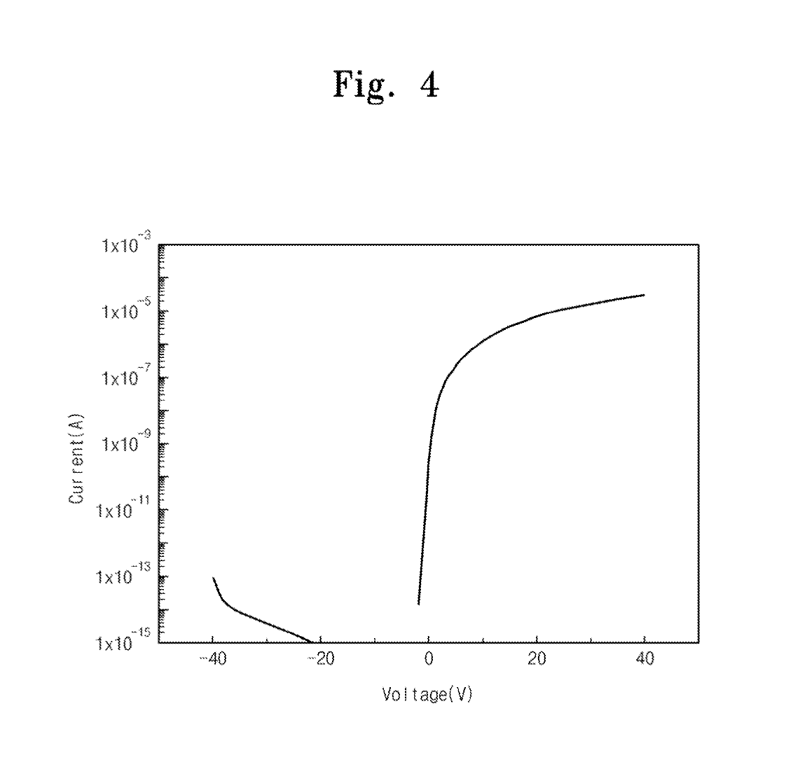

FIG. 4 is a graph showing voltage-current characteristics of an oxide semiconductor transistor. In FIG. 4, a horizontal axis indicates a level of a voltage applied to the gate electrode and a vertical axis indicates a level of a current output from the drain electrode.

Referring to FIG. 4, as the voltage (hereinafter, referred to as “gate voltage”) applied to the gate electrode of the oxide semiconductor transistor is increased from about 0 volts to about 40 volts with respect to the reference voltage, the current (hereinafter, referred to as “output voltage”) output from the drain electrode of the oxide semiconductor transistor is gradually increased. That is, the output current is non-linearly increased as the gate voltage is increased in a range from about 0 volts to about 40 volts. Accordingly, the thin film transistor may be operated as a switching device according to the voltage level.

However, the output voltage is lower than 10⁻¹⁵ volts in a range from about −20 volts to about 0 volts with respect to the reference voltage. This is because the depletion layer in which electrons and holes do not exist is formed in the semiconductor layer of the oxide semiconductor transistor when the gate voltage is in a range from about −20 volts to about 0 volts, and thus the current does not flow. Accordingly, the thin film transistor may serve as the insulating layer through which the current is substantially void.

Referring to FIG. 3 again, the reverse-bias voltage is applied to the base electrode 112, and the semiconductor layer 114 is changed to the depletion layer DEP to be used as the insulating layer. Thus, the semiconductor layer 114 does not need to be patterned. The reverse-bias voltage may be about −10 volts, but varied depending on the characteristics of the material applied to the semiconductor layer 114.

According to the display panel shown in FIGS. 2 and 3, since an etch process for patterning the semiconductor layer 114 does not need to be performed after forming the semiconductor layer 114, the semiconductor layer 114 may be prevented from being deteriorated in its characteristics. In addition, a photolithography process used to pattern the semiconductor layer 114 may be omitted, and thus a manufacturing cost of the display panel may be reduced and a manufacturing process of the display panel may be simplified.

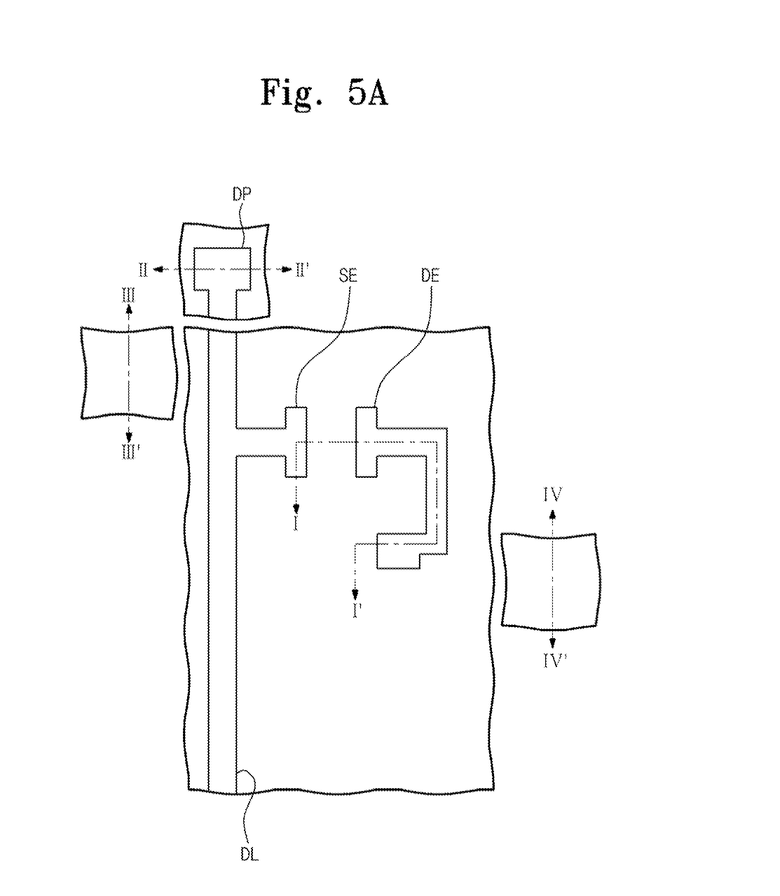

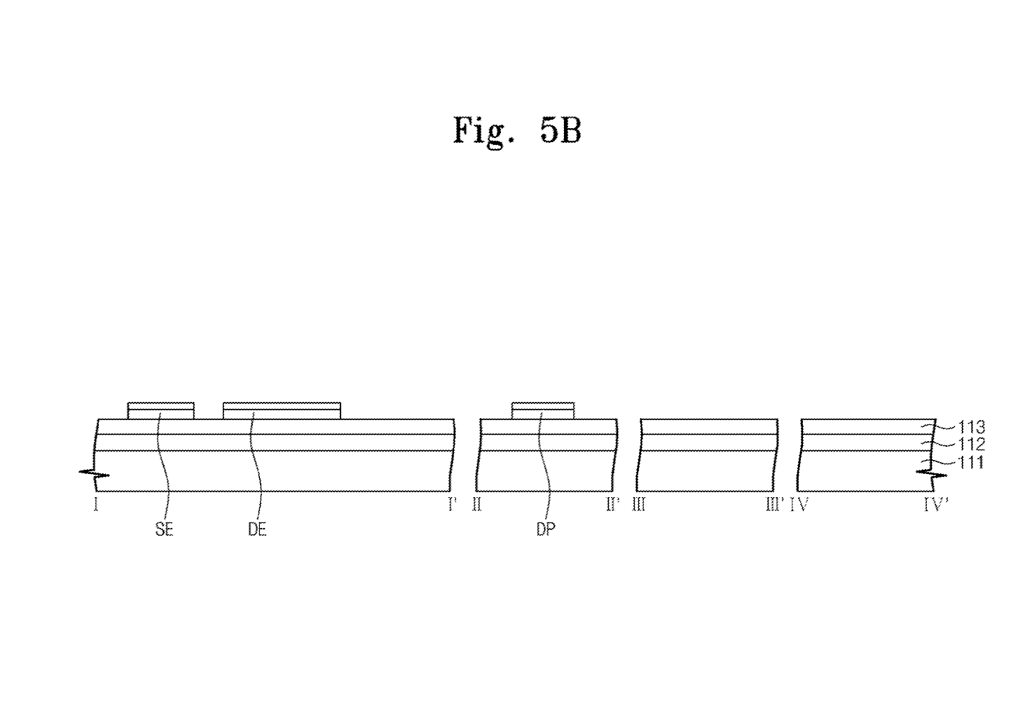

FIG. 5A is a plan view showing a result of performing a first photolithography process of a manufacturing method of a thin film transistor substrate according to an exemplary embodiment of the present invention, and FIG. 5B is cross-sectional views respectively taken along lines I-I′, II-II′, III-III′, and IV-IV′ of FIG. 5A.

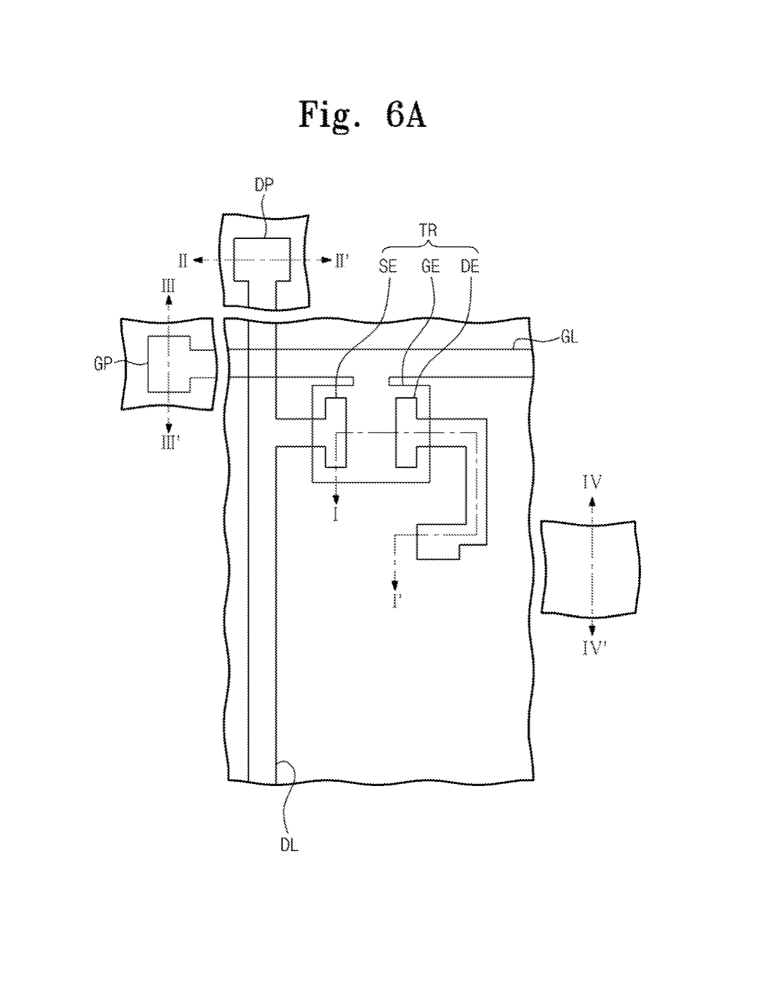

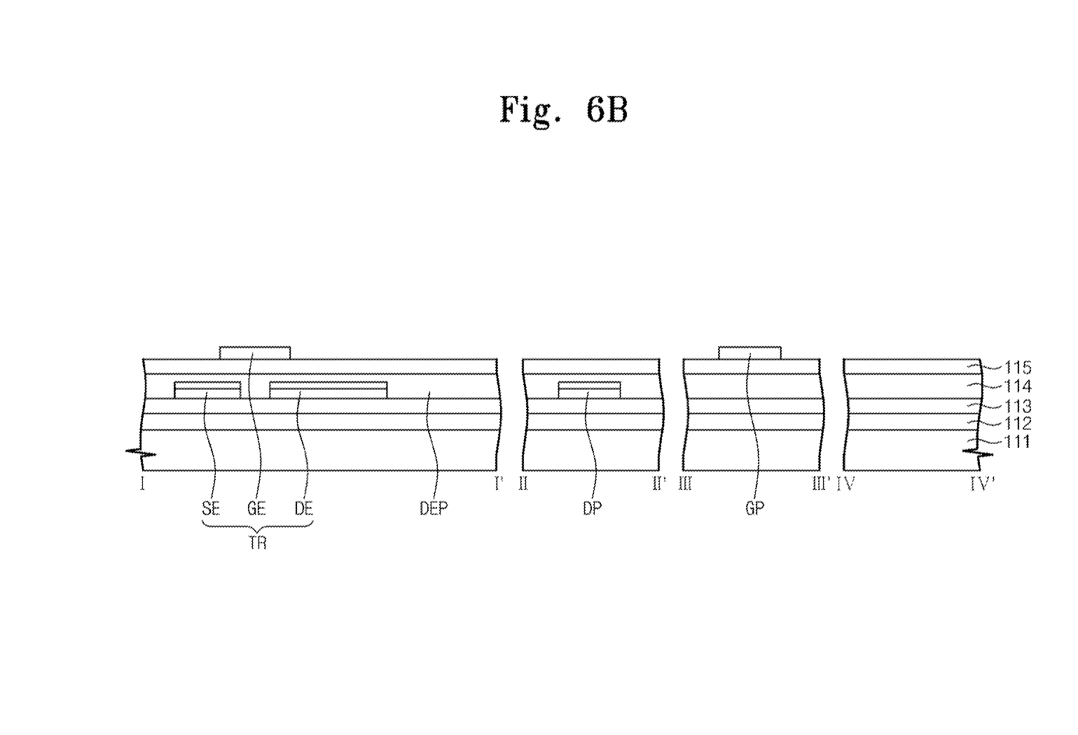

FIG. 6A is a plan view showing a result of performing a second photolithography process of a manufacturing method of a thin film transistor substrate according to an exemplary embodiment of the present invention, and FIG. 6B is cross-sectional views respectively taken along lines I-I′, II-II′, III-III′, and IV-IV′ of FIG. 6A.

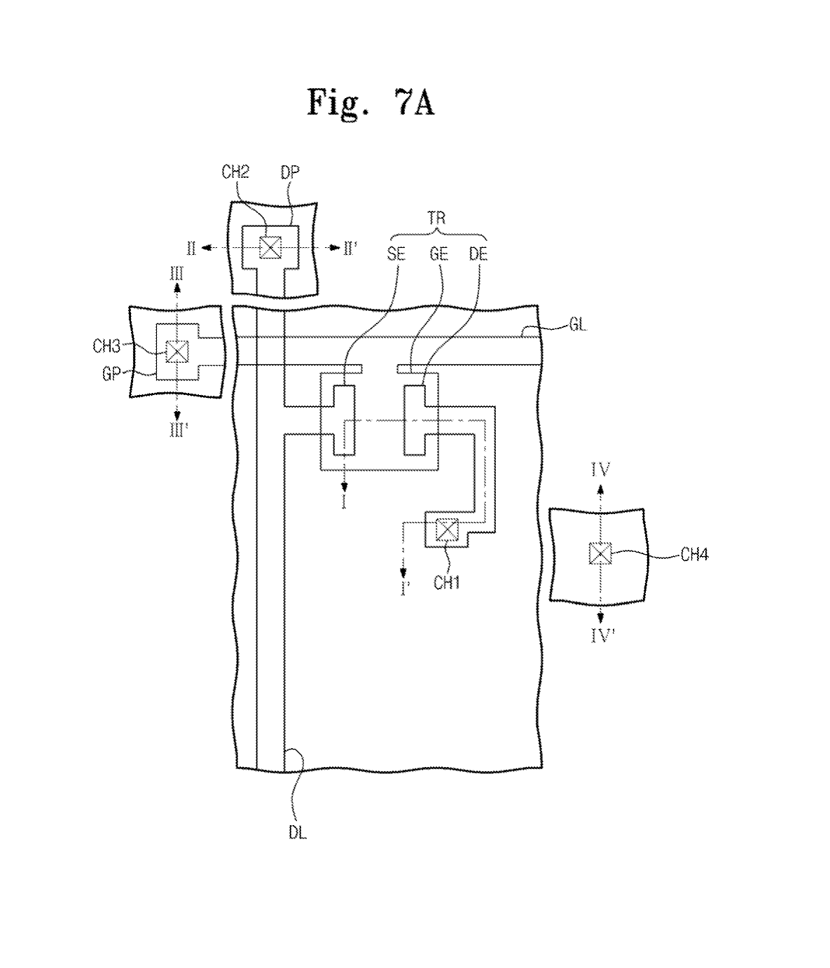

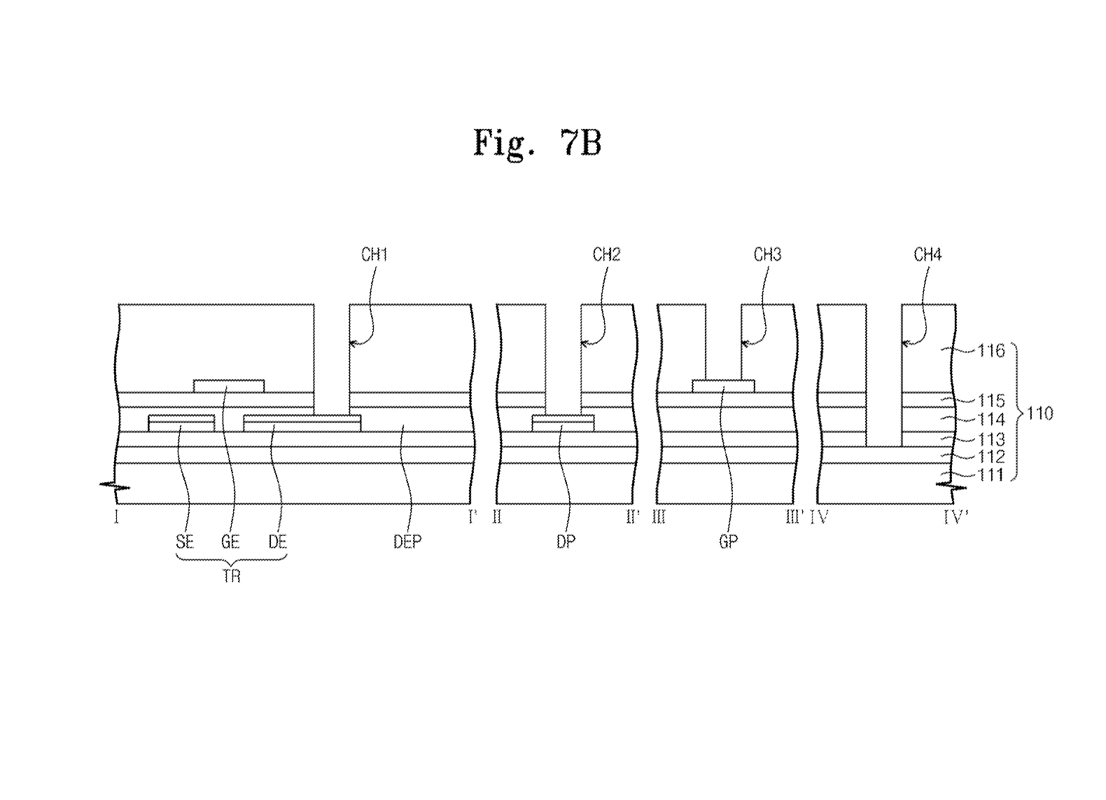

FIG. 7A is a plan view showing a result of performing a third photolithography process of a manufacturing method of a thin film transistor substrate according to an exemplary embodiment of the present invention, and FIG. 7B is cross-sectional views respectively taken along lines I-I′, II-II′, III-III′, and IV-IV′ of FIG. 7A.

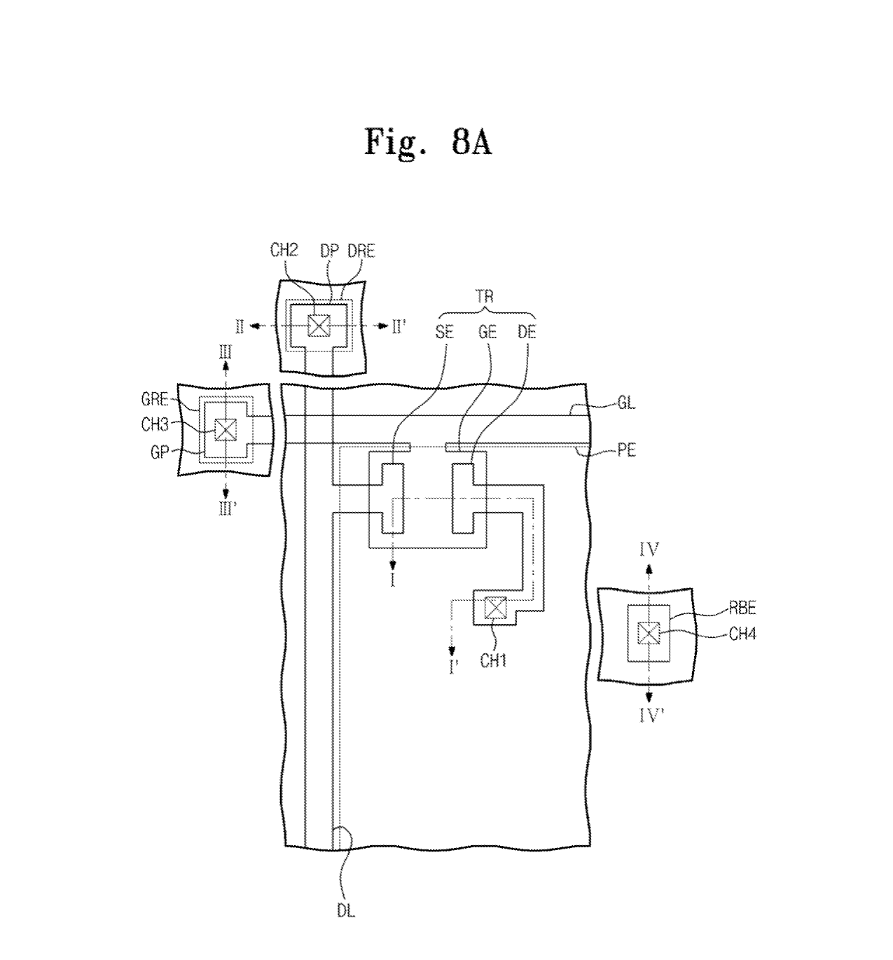

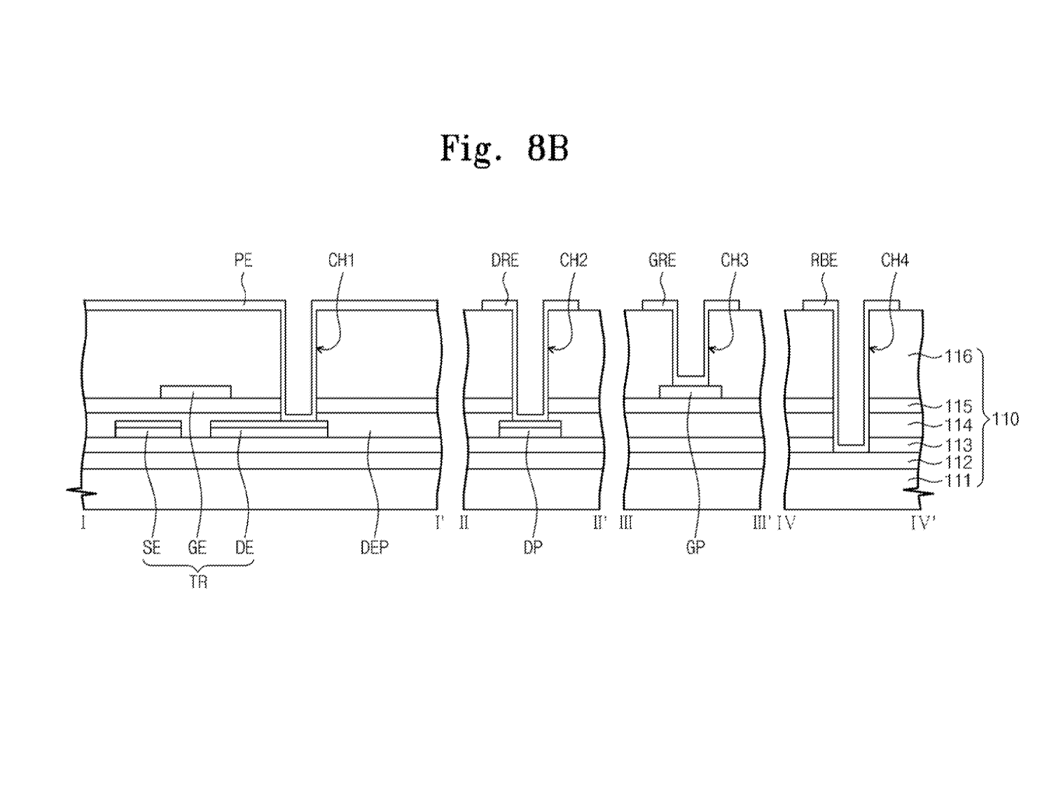

FIG. 8A is a plan view showing a result of performing a fourth photolithography process of a manufacturing method of a thin film transistor substrate according to an exemplary embodiment of the present invention, and FIG. 8B is cross-sectional views respectively taken along lines I-I′, II-II′, III-III′, and IV-IV′ of FIG. 8A.

Referring to FIGS. 5A and 5B, the base electrode 112 is formed on the base substrate 111 after preparing the base substrate 111. The base electrode 112 may be formed in a single or plural number to partially or entirely cover the upper surface of the base substrate 111. The base electrode 112 may be the transparent or non-transparent electrode. In detail, the base electrode 112 may be the transparent electrode including indium tin oxide (ITO), indium zinc oxide (IZO), indium tin zinc oxide (ITZO), or gallium zinc oxide (GZO), or the non-transparent electrode including an opaque metal material.

The first insulating layer 113 is disposed on the base electrode 112. The first insulating layer 113 may include an oxide material, a nitride material, or a transparent insulative material, e.g., silicon nitride (SiNx), silicon oxide (SiOx), etc.

The data line DL, the data pad DP, the source electrode SE, and the drain electrode DE are formed on the first insulating layer 113 by a first photolithography process. The source electrode SE, the drain electrode DE, and the data pad DP may have the double-layer structure of the first metal layer and the second metal layer disposed on the first metal layer. For instance, the first metal layer may include chromium (Cr) or oxide chromium (Cr₂O₃) and the second metal layer may include aluminum neodymium (AlNd).

Referring to FIGS. 6A and 6B, the semiconductor layer 114 is disposed on the first insulating layer 113, the source electrode SE, the drain electrode DE, and the data pad DP. The semiconductor layer 114 may include an oxide compound. In detail, the semiconductor layer 114 may include at least one of InGaZnO, ZnO, ZrInZnO, InZnO, InGaZnO₄, ZnInO, In2O₃, Ga₂O₃, HfInZnO, GaInZnO, HfO₂, SnO₂, WO₃, TiO₂, Ta₂O₅, In₂O₃SnO₂, MgZnO, ZnSnO₃, ZnSnO₄, CdZnO, CuAlO₂, CuGaO₂, Nb₂O₅, or TiSrO₃.

The method of forming the semiconductor layer 114 is as follows. The oxide compound in the liquid state is coated on the first insulating layer 113. The oxide compound in the liquid state may be coated by various methods, such as a screen printing method, a spin coating method, an ink-jet method, etc. Then, the coated oxide compound in the liquid state is heat-treated to form the semiconductor layer 114. In detail, the heat-treatment process is performed by using a furnace or a laser to vaporize an additive, e.g., solvent, contained in the oxide compound in the liquid state. In the case of using the laser, the heat-treatment process may be performed at a lower temperature than that of the furnace.

The second insulating layer 115 is formed on the semiconductor layer 114. The second insulating layer 115 may include the oxide material, the nitride material, or the transparent insulative material, for example, silicon nitride (SiNx) or silicon oxide (SiOx).

The gate line GL, the gate electrode GE, and the gate pad GP are formed on the second insulating layer 115 through a second photolithography process. In FIGS. 6A and 6B, the gate line GL, the gate electrode GE, and the gate pad GP have the single-layer structure, but the gate line GL, the gate electrode GE, and the gate pad GP may have the double-layer structure as the source electrode SE and the drain electrode DE.

Referring to FIGS. 7A and 7B, the third insulating layer 116 is formed on the gate line GL, the gate electrode GE, and the gate pad GP. After forming the third insulating layer 116, the first, second, third, and fourth contact holes CH1, CH2, CH3, and CH4 are formed by a third photolithography process.

The first contact hole CH1 is formed through the second insulating layer 115, the semiconductor layer 114, and the third insulating layer 116 to expose at least the portion of the drain electrode DE. The second contact hole CH2 is formed through the second insulating layer 115, the semiconductor layer 114, and the third insulating layer to expose the data pad DP. The third contact hole CH3 is formed through the third insulating layer 116 to expose the gate pad GP. The fourth contact hole CH4 is formed through the first insulating layer 113, the second insulating layer 115, the semiconductor layer 114, and the third insulating layer 116 to expose at least the portion of the base electrode 112.

Referring to FIGS. 8A and 8B, the pixel electrode PE, the data receiving electrode DRE, the gate receiving electrode GRE, and the reverse-bias input electrode RBE are formed on the third insulating layer 116 by a fourth photolithography process.

The pixel electrode PE is connected to the drain electrode DE through the first contact hole CH1 and the data receiving electrode DRE is connected to the data pad DP through the second contact hole CH2. The gate receiving electrode GRE is connected to the gate pad GP through the third contact hole CH3 and the reverse-bias input electrode RBE is connected to the base electrode 112 through the fourth contact hole CH4.

According to the manufacturing method of the thin film transistor shown in FIGS. 5A to 8A and 5B to 8B, the thin film transistor may be formed by the first and second photolithography processes and the thin film transistor substrate may be manufactured by the first to fourth photolithography processes.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A display panel comprising:
a substrate; and
a plurality of pixels disposed on the substrate, each pixel comprising:
a base electrode disposed on the substrate;
a first insulating layer disposed on the base electrode;
a source electrode disposed on the first insulating layer;
a drain electrode disposed on the first insulating layer and spaced apart from the source electrode;
a semiconductor layer disposed on the source electrode, the drain electrode, and the first insulating layer;
a second insulating layer disposed on the semiconductor layer; and
a gate electrode disposed on the second insulating layer and overlapped with the source electrode and the drain electrode.

2. The display panel of claim 1, wherein the semiconductor layer is a depletion layer when the base electrode is reverse-biased.

3. The display panel of claim 2, wherein the semiconductor layer between the source electrode and the drain electrode is a non-depletion layer when a gate-on voltage is applied to the gate electrode.

4. The display panel of claim 1, wherein the semiconductor layer comprises an oxide compound.

5. The display panel of claim 1, further comprising:
a third insulating layer disposed on the gate electrode; and
a pixel electrode electrically connected to the drain electrode through a first contact hole formed through the third insulating layer, the second insulating layer, and the semiconductor layer to expose at least a portion of the drain electrode.

6. The display panel of claim 5, further comprising:
a plurality of data lines disposed on the first insulating layer and extended in a first direction; and
a plurality of gate lines disposed on the second insulating layer and extended in a second direction crossing the first direction, wherein the source electrode is connected to a corresponding data line of the data lines and the gate electrode is connected to a corresponding gate line of the gate lines.

7. The display panel of claim 6, further comprising:
a data pad connected to at least an end of the corresponding data line of the data lines and disposed on the first insulating layer; and
a gate pad connected to at least an end of the corresponding gate line of the gate lines and disposed on the second insulating layer.

8. The display panel of claim 7, further comprising:
a data receiving electrode connected to the data pad through a second contact hole formed through the second insulating layer, the semiconductor layer, and the third insulating layer to expose the data pad to expose the data pad;
a gate receiving electrode connected to the gate pad through a third contact hole formed through the third insulating layer to expose the gate pad; and
a reverse-bias input electrode connected to the base electrode through the fourth contact hole formed through the first insulating layer, the second insulating layer, the semiconductor layer, and the third insulating layer to expose at least a portion of the base electrode.

9. A method of manufacturing a thin film transistor substrate, comprising:
forming a base electrode on a substrate;
forming a first insulating layer on the base electrode;
forming a source electrode and a drain electrode spaced apart from the source electrode on the first insulating layer;
forming a semiconductor layer on the source electrode, the drain electrode, and the first insulating layer;
forming a second insulating layer on the semiconductor layer;
forming a gate electrode on the second insulating layer to overlap with the source electrode and the drain electrode; and
forming a third insulating layer on the second insulating layer to cover the gate electrode.

10. The method of claim 9, further comprising:
forming a data pad on the first insulating layer; and
forming a gate pad on the second insulating layer, wherein the semiconductor layer comprises an oxide compound.

11. The method of claim 10, further comprising:
forming a first contact hole through the second insulating layer, the semiconductor layer, and the third insulating layer to expose at least a portion of the drain electrode;
forming a second contact hole through the second insulating layer, the semiconductor layer, and the third insulating layer to expose the data pad;
forming a third contact hole through the third insulating layer to expose the gate pad; and
forming a fourth contact hole through the first insulating layer, the second insulating layer, the semiconductor layer, and the third insulating layer to expose at least a portion of the base electrode.

12. The method of claim 11, further comprising forming a pixel electrode connected to the drain electrode through the first contact hole, a data receiving electrode connected to the data pad through the second contact hole, a gate receiving electrode connected to the gate pad through the third contact hole, and a reverse-bias input electrode connected to the base electrode through the fourth contact hole on the third insulating layer.

13. The method of claim 12, wherein the source electrode and the drain electrode are formed by a first photolithography process, the gate electrode is formed by a second photolithography process, the first to fourth contact holes are formed by a third photolithography process, and the pixel electrode, the data receiving electrode, the gate receiving electrode, and the reverse-bias input electrode are formed by a fourth photolithography process.

14. The method of claim 9, wherein the forming of the semiconductor layer comprises:
coating an oxide compound in a liquid state on the first insulating layer; and
performing a heat-treatment process on the coated oxide compound to form the semiconductor layer.

15. The method of claim 14, wherein the coating of the oxide compound is performed by a spin-coating method.

16. The method of claim 14, wherein the heat-treatment process on the coated oxide compound is performed by a laser.

17. A thin film transistor substrate comprising:
a base electrode disposed on a substrate;
a first insulating layer disposed on the base substrate;
a source electrode disposed on the first insulating layer;
a drain electrode disposed on the first insulating layer to be spaced apart from the source electrode;
a semiconductor layer disposed on the source electrode, the drain electrode, and the first insulating layer;
a second insulating layer disposed on the semiconductor layer; and
a gate electrode disposed on the second insulating layer to overlap with the source electrode and the drain electrode.

18. The thin film transistor substrate of claim 17, wherein the semiconductor layer is a depletion layer when the base electrode is reverse-biased.

19. The thin film transistor substrate of claim 18, wherein the semiconductor layer between the source electrode and the drain electrode is a non-depletion layer when a gate-on voltage is applied to the gate electrode.

20. The thin film transistor substrate of claim 17, wherein the semiconductor layer comprises an oxide compound.
